(19) United States
(12) Patent Application Publication
(10) Pub. No.: US 2026/0045914 A1
(43) Pub. Date: Feb. 12, 2026

(54) ADAPTIVE MULTI-LEVEL ENVELOPE TRACKING DESIGN FOR DIGITAL ENVELOPE TRACKERS

(71) Applicant: Samsung Electronics Co., Ltd., Suwon-si (KR)

(72) Inventors: Navneet Sharma, Allen, TX (US); Won Suk Choi, McKinney, TX (US); Chance Anthony Tarver, Arlington, TX (US); Gang Xu, Allen, TX (US)

(21) Appl. No.: 19/201,803

(22) Filed: May 7, 2025

Related U.S. Application Data
(60) Provisional application No. 63/681,001, filed on Aug. 8, 2024.

(51) Int. Cl. H03F 1/02; H03F 3/24

(52) U.S. Cl. CPC H03F 1/0227; H03F 3/245; H03F 2200/102; H03F 2200/451

(57) ABSTRACT

Methods and systems for adaptive multi-level digital envelope tracking. A method includes supplying a supply voltage to a digital envelope tracking system then generating a first voltage and a second voltage using a supply generator based on the supply voltage level. The method further includes generating one or more additional voltages using a voltage level generator where each of the one or more additional voltages have a voltage level between the first and second voltage level. The method also includes adjusting the one or more additional voltages to adapt to a radio frequency load by adjusting the first voltage level, the second voltage level, or both, and supplying the first voltage, the second voltage, and the one or more additional voltages to a power amplifier.

### CROSS-REFERENCE TO RELATED APPLICATIONS AND CLAIM OF PRIORITY

The present application claims priority to U.S. Provisional Patent Application No. 63/681,001, filed on Aug. 8, 2024. The contents of the above-identified patent documents are incorporated herein by reference.

### TECHNICAL FIELD

The present disclosure relates generally to wireless communication systems. more specifically, the present disclosure relates to a system and method for adaptive multi-level digital envelope tracking.

### BACKGROUND

In 6G extreme-MIMO systems, there are likely to be over a thousand power amplifiers in a single base station. These power amplifiers typically consume the majority of the power budget of the base station. Moreover, the load on the transmitter or the output power transmitted by the power amplifier are dependent on the demands of the end user on the base station power amplifier. The demand has short-term variation due to peak-to-average power ratio of the modulated signal and a long-term variation due to user load which varies on an hourly basis. For example, nighttime demand is significantly different than daytime peak load. The digital envelope tracking system supporting such transmitters may need to generate large numbers of discrete levels to support all use cases. However, generating large numbers of discrete levels significantly increases the cost, complexity, and degrades the efficiency gains of the system.

Accordingly, there is a need for systems and methods for improved envelope tracking systems that overcome these challenges.

### SUMMARY

The present disclosure relates generally to wireless communication systems and, more specifically, the present disclosure relates to a system and method for adaptive multi-level digital envelope tracking.

In one embodiment, a method is provided. The method includes supplying a supply voltage having a supply voltage level to a digital envelope tracking system then generating a first voltage having a first voltage level and a second voltage having a second voltage level using a supply generator of the digital envelope tracking system based on the supply voltage level. The method further includes generating one or more additional voltages using a voltage level generator of the digital envelope tracking system. Each of the one or more additional voltages have an additional voltage level between the first voltage level and the second voltage level. The method also includes adjusting the additional voltage level of the one or more additional voltages to adapt to a radio frequency (RF) load by adjusting the first voltage level, the second voltage level, or both, and supplying the first voltage, the second voltage, and the one or more additional voltages to a power amplifier.

In another embodiment, an electronic device is provided. The electronic device includes a processor configured to cause the electronic device to supply a supply voltage having a supply voltage level to a digital envelope tracking system then generate a first voltage having a first voltage level and a second voltage having a second voltage level using a supply generator of the digital envelope tracking system based on the supply voltage level. The processor is further configured to cause the electronic device to generate one or more additional voltages using a voltage level generator of the digital envelope tracking system. Each of the one or more additional voltages having an additional voltage level between the first voltage level and the second voltage level. The processor is also configured to cause the electronic device to adjust the additional voltage level of the one or more additional voltages to adapt to a radio frequency (RF) load by adjusting the first voltage level, the second voltage level, or both, and supply the first voltage, the second voltage, and the one or more additional voltages to a power amplifier.

In yet another embodiment, a non-transitory computer-readable medium is provided. The non-transitory computer-readable medium includes program code, that when executed by at least one processor of an electronic device, causes the electronic device to supply a supply voltage having a supply voltage level to a digital envelope tracking system to the digital envelope tracking system, then generate a first voltage having a first voltage level and a second voltage having a second voltage level using a supply generator of the digital envelope tracking system based on the supply voltage level. The non-transitory computer-readable medium further includes program code, that when executed by at least one processor of an electronic device, causes the electronic device to generate one or more additional voltages using a voltage level generator of the digital envelope tracking system. Each of the one or more additional voltages having an additional voltage level between the first voltage level and the second voltage level. The non-transitory computer-readable medium also includes program code, that when executed by at least one processor of an electronic device, causes the electronic device to adjust the additional voltage level of the one or more additional voltages to adapt to a radio frequency (RF) load by adjusting the first voltage level, the second voltage level, or both, and supply the first voltage, the second voltage, and the one or more additional voltages to a power amplifier.

Other technical features may be readily apparent to one skilled in the art from the following figures, descriptions, and claims.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit”, “receive”, and “communicate”, as well as derivatives thereof, encompass both direct and indirect communication. The terms “include” and “comprise”, as well as derivatives thereof, mean inclusion without limitation. The term “or” is inclusive, meaning and/or. The phrase “associated with”, as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system, or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below may be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data may be permanently stored and media where data may be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example wireless network according to embodiments of the present disclosure;

FIG. 2 illustrates an example gNB according to embodiments of the present disclosure;

FIG. 3 illustrates an example UE according to embodiments of the present disclosure;

FIG. 4 illustrates an example power envelope of a power amplifier;

FIG. 5A illustrates an example adaptive multi-level digital envelope tracking system according to embodiments of the present disclosure;

FIG. 5B illustrates an example radio frequency envelope of the adaptive multi-level digital envelope tracking system of FIG. 5A according to embodiments of the present disclosure;

FIG. 6 illustrates an example method for adaptive multi-level digital envelope tracking according to embodiments of the present disclosure; and

FIG. 7 illustrates an example voltage level chart of an adaptive multi-level digital envelope tracking system according to embodiments of the present disclosure.

### DETAILED DESCRIPTION

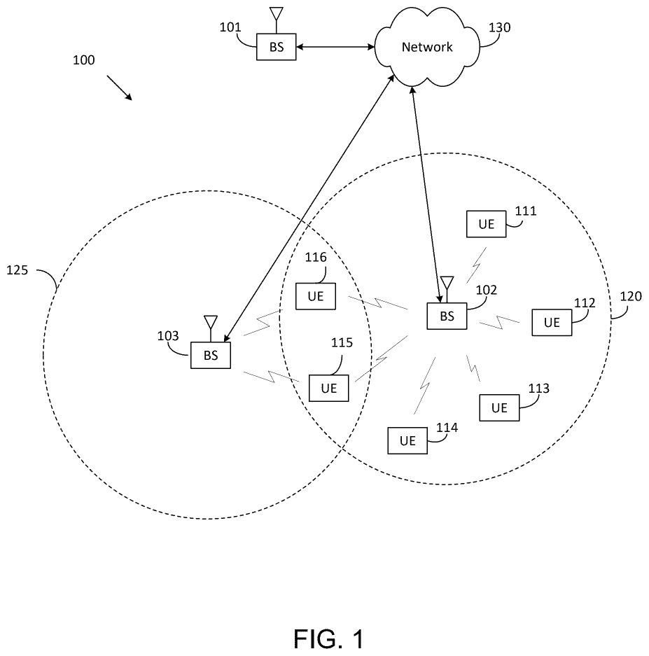

FIG. 1 through FIG. 7, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

As introduced above, power amplifiers typically consume the majority of the power budget of the base station. Moreover, their power-added efficiency (PAE), a performance metric of a power amplifier, is often as low as 20%. The lower PAE is indicative of wasted power that contributes significantly to thermal concerns and increases the operational expenditure costs of a system. Additionally, the PAE tends to be lower for higher RF frequencies, further exacerbating the challenge for 6G design where Frequency Range 3 upper mid-band is being considered.

Digital envelope tracking (DET) improves the PAE of a power amplifier by reducing the bias voltage whenever possible. When designing a DET system, the baseline solution is to choose between discrete voltage levels that linearly span a range of minimum operating voltages for the power amplifier and some high voltages. In multicarrier waveforms with a high peak-to-average power ratio (PAPR), this may lead to suboptimal DET levels, reducing the power added efficiency (PAE) improvement achievable from the DET system. The primary problem is poor selection DET levels, leading to poor improvement in PAE when deploying DET. For example, when the user load or RF output power decreases, the selected voltage level for the power amplifier is correspondingly reduced, for example, between four evenly-spaced voltage levels (e.g., set at 100%, 50%, 25%, and 10% of the peak power of the power amplifier). For high RF loads, such as 100% and 50%, the four levels of the DET system are exercised taking care of both PAPR variation and load variation in the RF envelope. But for lower levels, such as at 25% and 10%, the effective number of levels for load condition reduces. For example, at a 25% load condition, two levels may be used while the remaining higher two levels will not. Similarly, for the lowest load level of 10%, only the lowest level may be used which also means there need not be any voltage level switching from a DET circuit. This reduces the efficiency of the system significantly and the efficacy of the digital envelope tracking system.

Accordingly, the present disclosure provides systems and methods for adaptive multi-level digital envelope tracking. In particular, the present disclosure provides systems and methods for adjusting one or more voltage levels to adapt to an RF load by temporarily connecting a power amplifier to a static voltage level while adjusting the one or more voltage levels. Adjusting the one or more voltage levels may include changing a DC-DC converter while a power amplifier level is connected to a lowest voltage level or a highest voltage level. As described herein, the present disclosure includes systems and methods that adaptively change voltage levels of the DET system (such as at a supply modulator) to cover large variation in the RF load.

To meet the demand for wireless data traffic having increased since deployment of 4G communication systems and to enable various vertical applications, 5G/NR communication systems have been developed and are currently being deployed. The 5G/NR communication system is considered to be implemented in higher frequency (mmWave) bands, e.g., 28 GHz or 60 GHz bands, so as to accomplish higher data rates or in lower frequency bands, such as 6 GHz, to enable robust coverage and mobility support. To decrease propagation loss of the radio waves and increase the transmission distance, the beamforming, massive multiple-input multiple-output (MIMO), full dimensional MIMO (FD-MIMO), array antenna, an analog beam forming, large scale antenna techniques are discussed in 5G/NR communication systems.

In addition, in 5G/NR communication systems, development for system network improvement is under way based on advanced small cells, cloud radio access networks (RANs), ultra-dense networks, device-to-device (D2D) communication, wireless backhaul, moving network, cooperative communication, coordinated multi-points (CoMP), reception-end interference cancelation and the like.

The discussion of 5G systems and frequency bands associated therewith is for reference as certain embodiments of the present disclosure may be implemented in 5G systems. However, the present disclosure is not limited to 5G systems or the frequency bands associated therewith, and embodiments of the present disclosure may be utilized in connection with any frequency band. For example, aspects of the present disclosure may also be applied to deployment of 5G communication systems, 6G or even later releases which may use terahertz (THz) bands.

FIGS. 1-3 below describe various embodiments implemented in wireless communications systems and with the use of orthogonal frequency division multiplexing (OFDM) or orthogonal frequency division multiple access (OFDMA) communication techniques. The descriptions of FIGS. 1-3 are not meant to imply physical or architectural limitations to the manner in which different embodiments may be implemented. Different embodiments of the present disclosure may be implemented in any suitably arranged communications system.

FIG. 1 illustrates an example wireless network according to embodiments of the present disclosure. The embodiment of the wireless network shown in FIG. 1 is for illustration only. Other embodiments of the wireless network 100 could be used without departing from the scope of this disclosure.

As shown in FIG. 1, the wireless network includes a gNB 101 (e.g., base station, BS), a gNB 102, and a gNB 103. The gNB 101 communicates with the gNB 102 and the gNB 103. The gNB 101 also communicates with at least one network 130, such as the Internet, a proprietary Internet Protocol (IP) network, or other data network.

The gNB 102 provides wireless broadband access to the network 130 for a first plurality of user equipments (UEs) within a coverage area 120 of the gNB 102. The first plurality of UEs includes a UE 111, which may be located in a small business; a UE 112, which may be located in an enterprise; a UE 113, which may be a WiFi hotspot; a UE 114, which may be located in a first residence; a UE 115, which may be located in a second residence; and a UE 116, which may be a mobile device, such as a cell phone, a wireless laptop, a wireless PDA, or the like. The gNB 103 provides wireless broadband access to the network 130 for a second plurality of UEs within a coverage area 125 of the gNB 103. The second plurality of UEs includes the UE 115 and the UE 116. In some embodiments, one or more of the gNBs 101-103 may communicate with each other and with the UEs 111-116 using 5G/NR, long term evolution (LTE), long term evolution-advanced (LTE-A), WiMAX, WiFi, or other wireless communication techniques.

Depending on the network type, the term “base station” or “BS” may refer to any component (or collection of components) configured to provide wireless access to a network, such as transmit point (TP), transmit-receive point (TRP), an enhanced base station (eNodeB or eNB), a 5G/NR base station (gNB), a macrocell, a femtocell, a WiFi access point (AP), or other wirelessly enabled devices. Base stations may provide wireless access in accordance with one or more wireless communication protocols, e.g., 5G/NR 3^{rd} generation partnership project (3GPP) NR, long term evolution (LTE), LTE advanced (LTE-A), high speed packet access (HSPA), Wi-Fi 802.11a/b/g/n/ac, etc. For the sake of convenience, the terms “BS” and “TRP” are used interchangeably in this patent document to refer to network infrastructure components that provide wireless access to remote terminals. Also, depending on the network type, the term “user equipment” or “UE” may refer to any component such as “mobile station”, “subscriber station”, “remote terminal”, “wireless terminal”, “receive point”, or “user device”. For the sake of convenience, the terms “user equipment” and “UE” are used in this patent document to refer to remote wireless equipment that wirelessly accesses a BS, whether the UE is a mobile device (such as a mobile telephone or smartphone) or is normally considered a stationary device (such as a desktop computer or vending machine).

Dotted lines show the approximate extents of the coverage areas 120 and 125, which are shown as approximately circular for the purposes of illustration and explanation only. It should be clearly understood that the coverage areas associated with gNBs, such as the coverage areas 120 and 125, may have other shapes, including irregular shapes, depending upon the configuration of the gNBs and variations in the radio environment associated with natural and man-made obstructions.

Although FIG. 1 illustrates one example of a wireless network, various changes may be made to FIG. 1. For example, the wireless network could include any number of gNBs and any number of UEs in any suitable arrangement. Also, the gNB 101 could communicate directly with any number of UEs and provide those UEs with wireless broadband access to the network 130. Similarly, each gNB 102-103 could communicate directly with the network 130 and provide UEs with direct wireless broadband access to the network 130. Further, the gNBs 101, 102, and/or 103 could provide access to other or additional external networks, such as external telephone networks or other types of data networks.

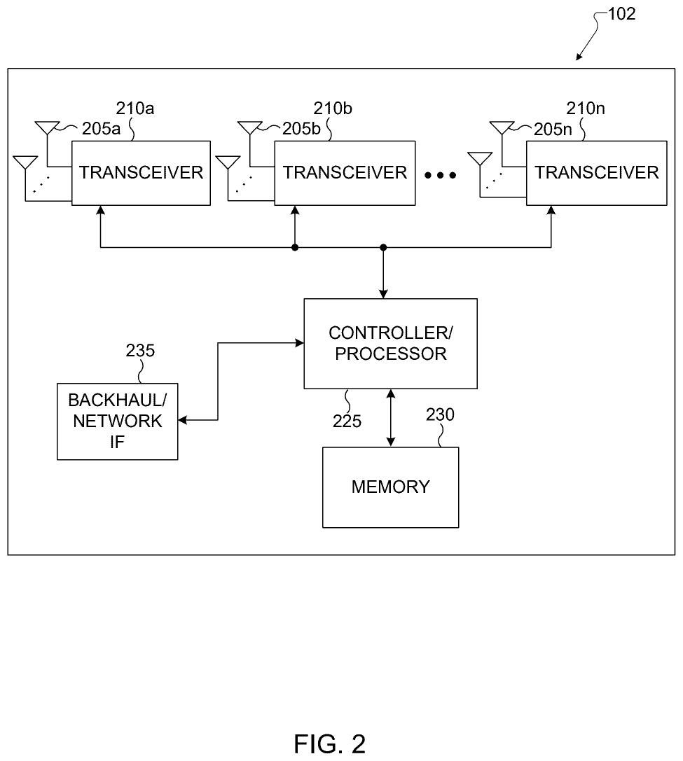

FIG. 2 illustrates an example gNB 102 according to embodiments of the present disclosure. The embodiment of the gNB 102 illustrated in FIG. 2 is for illustration only, and the gNBs 101 and 103 of FIG. 1 could have the same or similar configuration. However, gNBs come in a wide variety of configurations, and FIG. 2 does not limit the scope of this disclosure to any particular implementation of a gNB.

As shown in FIG. 2, the gNB 102 includes multiple antennas 205a-205n, multiple transceivers 210a-210n, a controller/processor 225, a memory 230, and a backhaul or network interface 235.

The transceivers 210a-210n receive, from the antennas 205a-205n, incoming RF signals, such as signals transmitted by UEs in the network 100. The transceivers 210a-210n down-convert the incoming RF signals to generate IF or baseband signals. The IF or baseband signals are processed by receive (RX) processing circuitry in the transceivers 210a-210n and/or controller/processor 225, which generates processed baseband signals by filtering, decoding, and/or digitizing the baseband or IF signals. The controller/processor 225 may further process the baseband signals.

Transmit (TX) processing circuitry in the transceivers 210a-210n and/or controller/processor 225 receives analog or digital data (such as voice data, web data, e-mail, or interactive video game data) from the controller/processor 225. The TX processing circuitry encodes, multiplexes, and/or digitizes the outgoing baseband data to generate processed baseband or IF signals. The transceivers 210a-210n up-converts the baseband or IF signals to RF signals that are transmitted via the antennas 205a-205n.

The controller/processor 225 may include one or more processors or other processing devices that control the overall operation of the gNB 102. For example, the controller/processor 225 could control the reception of UL channel signals and the transmission of DL channel signals by the transceivers 210a-210n in accordance with well-known principles. The controller/processor 225 could support additional functions as well, such as more advanced wireless communication functions. For instance, the controller/processor 225 could support beam forming or directional routing operations in which outgoing/incoming signals from/to multiple antennas 205a-205n are weighted differently to effectively steer the outgoing signals in a desired direction. Any of a wide variety of other functions could be supported in the gNB 102 by the controller/processor 225.

The controller/processor 225 is also capable of executing programs and other processes resident in the memory 230, such as an OS. The controller/processor 225 may move data into or out of the memory 230 as required by an executing process.

The controller/processor 225 is also coupled to the backhaul or network interface 235. The backhaul or network interface 235 allows the gNB 102 to communicate with other devices or systems over a backhaul connection or over a network. The interface 235 could support communications over any suitable wired or wireless connection(s). For example, when the gNB 102 is implemented as part of a cellular communication system (such as one supporting 5G/NR, LTE, or LTE-A), the interface 235 could allow the gNB 102 to communicate with other gNBs over a wired or wireless backhaul connection. When the gNB 102 is implemented as an access point, the interface 235 could allow the gNB 102 to communicate over a wired or wireless local area network or over a wired or wireless connection to a larger network (such as the Internet). The interface 235 includes any suitable structure supporting communications over a wired or wireless connection, such as an Ethernet or transceiver.

The memory 230 is coupled to the controller/processor 225. Part of the memory 230 could include a RAM, and another part of the memory 230 could include a Flash memory or other ROM.

Although FIG. 2 illustrates one example of gNB 102, various changes may be made to FIG. 2. For example, the gNB 102 could include any number of each component shown in FIG. 2. Also, various components in FIG. 2 could be combined, further subdivided, or omitted and additional components could be added according to particular needs.

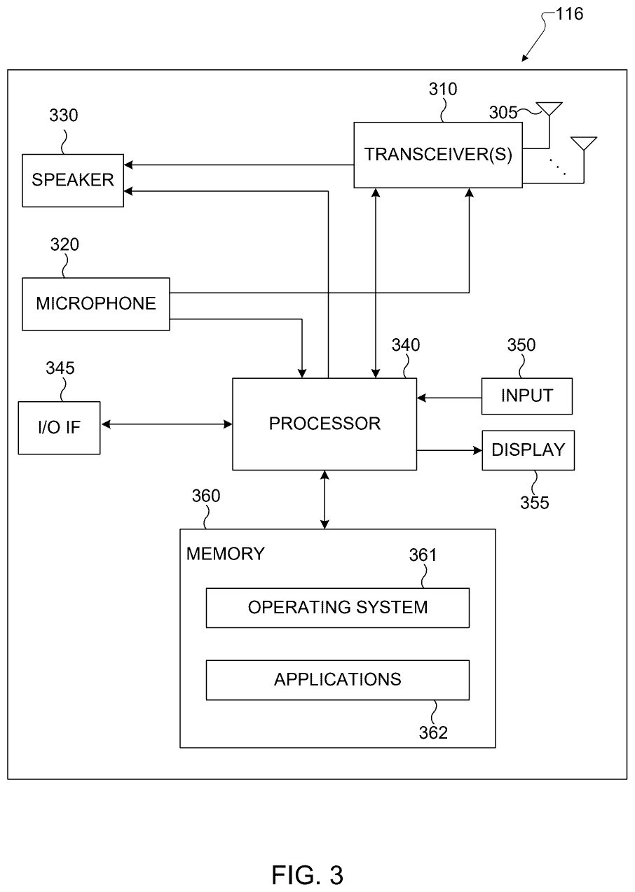

FIG. 3 illustrates an example UE 116 according to embodiments of the present disclosure. The embodiment of the UE 116 illustrated in FIG. 3 is for illustration only, and the UEs 111-115 of FIG. 1 could have the same or similar configuration. However, UEs come in a wide variety of configurations, and FIG. 3 does not limit the scope of this disclosure to any particular implementation of a UE.

As shown in FIG. 3, the UE 116 includes antenna(s) 305, a transceiver(s) 310, and a microphone 320. The UE 116 also includes a speaker 330, a processor 340, an input/output (I/O) interface (IF) 345, an input 350, a display 355, and a memory 360. The memory 360 includes an operating system (OS) 361 and one or more applications 362.

The transceiver(s) 310 receives, from the antenna 305, an incoming RF signal transmitted by a gNB of the network 100. The transceiver(s) 310 down-converts the incoming RF signal to generate an intermediate frequency (IF) or baseband signal. The IF or baseband signal is processed by RX processing circuitry in the transceiver(s) 310 and/or processor 340, which generates a processed baseband signal by filtering, decoding, and/or digitizing the baseband or IF signal. The RX processing circuitry sends the processed baseband signal to the speaker 330 (such as for voice data) or is processed by the processor 340 (such as for web browsing data).

TX processing circuitry in the transceiver(s) 310 and/or processor 340 receives analog or digital voice data from the microphone 320 or other outgoing baseband data (such as web data, e-mail, or interactive video game data) from the processor 340. The TX processing circuitry encodes, multiplexes, and/or digitizes the outgoing baseband data to generate a processed baseband or IF signal. The transceiver(s) 310 up-converts the baseband or IF signal to an RF signal that is transmitted via the antenna(s) 305.

The processor 340 may include one or more processors or other processing devices and execute the OS 361 stored in the memory 360 in order to control the overall operation of the UE 116. For example, the processor 340 could control the reception of DL channel signals and the transmission of UL channel signals by the transceiver(s) 310 in accordance with well-known principles. In some embodiments, the processor 340 includes at least one microprocessor or microcontroller.

The processor 340 is also capable of executing other processes and programs resident in the memory 360. The processor 340 may move data into or out of the memory 360 as required by an executing process. In some embodiments, the processor 340 is configured to execute the applications 362 based on the OS 361 or in response to signals received from gNBs or an operator. The processor 340 is also coupled to the I/O interface 345, which provides the UE 116 with the ability to connect to other devices, such as laptop computers and handheld computers. The I/O interface 345 is the communication path between these accessories and the processor 340.

The processor 340 is also coupled to the input 350, which includes for example, a touchscreen, keypad, etc., and the display 355. The operator of the UE 116 may use the input 350 to enter data into the UE 116. The display 355 may be a liquid crystal display, light emitting diode display, or other display capable of rendering text and/or at least limited graphics, such as from web sites.

The memory 360 is coupled to the processor 340. Part of the memory 360 could include a random-access memory (RAM), and another part of the memory 360 could include a Flash memory or other read-only memory (ROM).

Although FIG. 3 illustrates one example of UE 116, various changes may be made to FIG. 3. For example, various components in FIG. 3 could be combined, further subdivided, or omitted and additional components could be added according to particular needs. As a particular example, the processor 340 could be divided into multiple processors, such as one or more central processing units (CPUs) and one or more graphics processing units (GPUs). In another example, the transceiver(s) 310 may include any number of transceivers and signal processing chains and may be connected to any number of antennas. Also, while FIG. 3 illustrates the UE 116 configured as a mobile telephone or smartphone, UEs could be configured to operate as other types of mobile or stationary devices.

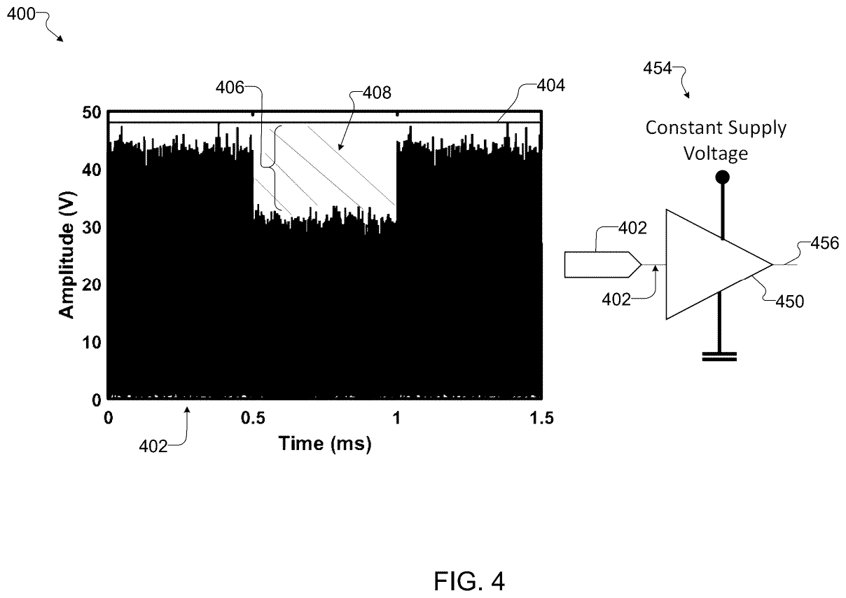

The TX processing circuitry of the gNB 101 may also include one or more power amplifiers coupled to one or more digital-to-analog converters and configured to amplify the baseband signal prior to transmission using the antenna. The one or more power amplifiers receive a supply voltage sufficient to cover the signal envelope of the baseband signal, as shown in FIG. 4.

FIG. 4 illustrates an example power envelope 400 of a power amplifier 450. As shown in FIG. 4, the power envelope 400, which may be represented as amplitude voltage over time, includes a RF envelope 402 representative of a baseband signal supplied to the power amplifier 450 from the DAC 452. In response to receiving the RF envelope 402, the power amplifier 450, using a constant supply voltage source 454 provides a PA supply voltage 404 to generate an output signal 456. The PA supply voltage 404 may need to have a voltage level (e.g., 48 volts as shown) greater than the RF envelope 402 to be effective. The RF envelope 402, however, fluctuates over time, creating a gap 406 between the RF envelope 402 and the PA supply voltage 404. The gap 406 creates an area of wasted energy 408 as the PA supply voltage 404 remains constant despite the RF envelope 402 changing voltage levels over time.

Further, the gap 406 forces the power amplifier 450 to operate in a power backoff mode. In a power backoff mode, the power amplifier 450 operates at a reduced power level below its highest output, intentionally lowering the signal received from the DAC 452 to maintain linearity and avoid distortion, especially when dealing with signals that have large peaks in power, ensuring the power amplifier 450 stays within its linear operating region even during high signal bursts from the DAC 452. While operating in backoff mode may improve signal quality, it usually comes at the cost of reduced power efficiency as the power amplifier 450 is not operating at its peak power output. In particular, when the power amplifier 450 operates in a power backoff mode, its power added efficiency (PAE) typically decreases significantly, reducing the effectiveness of the power amplifier 450 in amplifying the RF envelope 402.

Although FIG. 4 illustrates one example of a power envelope of a power amplifier, various changes may be made to FIG. 4. For example, the baseband signal may fluctuate between more than two voltage levels, such as between three or more voltage levels, such as between 4 or more voltage levels.

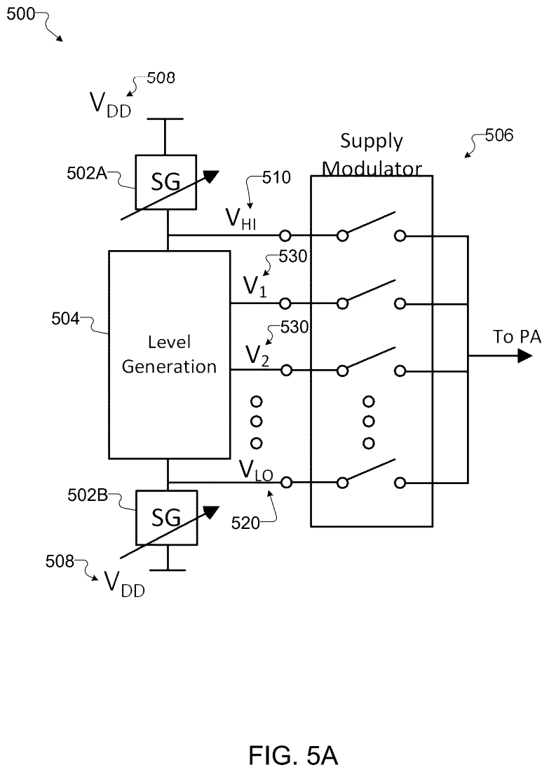

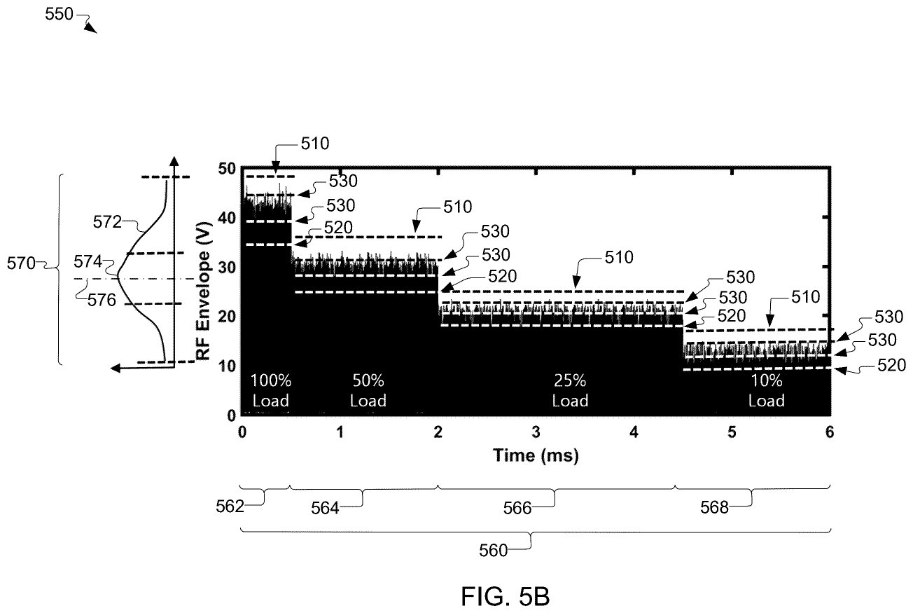

To improve power efficiency, the area of wasted energy 408 should be minimized between the RF envelope 402 and the PA supply voltage 404. This may be accomplished by configuring the power amplifier 450 to apply adaptive voltage levels that track or change with the RF envelope 402, for example, in an adaptive multi-level digital envelope tracking system as shown in FIGS. 5A-5B.

FIG. 5A illustrates an example adaptive multi-level digital envelope tracking (DET) module 500 according to embodiments of the present disclosure. For ease of explanation, the adaptive multi-level DET module 500 will be described as including one or more components of the wireless network 100 of FIG. 1, such as the gNB 102; however, the adaptive multi-level DET module 500 could be implemented using any other suitable device or system. The embodiment of the adaptive multi-level DET module 500 shown in FIG. 5A is for illustration only. Other embodiments of the adaptive multi-level DET module 500 could be used without departing from the scope of this disclosure.

As shown in FIG. 5A, the adaptive multi-level DET module 500 includes a first supply generator 502A, a second supply generator 502B, a voltage level generator 504, and a supply modulator 506. The supply generator 502A generates a first voltage 510 having a first voltage 510 value from a supply voltage 508 having a supply voltage level and a second voltage 520 having a second voltage 520 value from the supply voltage 508 for the DET system to operate on. For example, the first supply generator 502A may be a DC-DC converter, such as a buck converter, which converts the supply voltage level into a lower voltage (e.g., the first voltage 510 level) using switches, an inductor, and a capacitor to reduce the supply voltage level. In such embodiments, the supply generator 502 may have a high-side switch that controls current flow through the inductor, which stores the current as energy in its magnetic field. The stored energy is then transferred out, charging the capacitor. The capacitor then discharges, producing the first voltage 510 level. The second voltage 520 level may be generated similarly using a second supply generator 502B.

The voltage level generator 504 generates one or more additional voltages 530 as options to connect to PA supply node where each of the one or more additional voltages 530 have an additional voltage level between the first voltage 510 value and the second voltage 520 value.

The voltage levels (e.g., the first voltage 510, the second voltage 520, and the one or more additional voltages 530) of the DET module 500 are derived from the supply voltage 508. The supply voltage 508 is the highest DC supply (V_{DD}) connected to the DET module 500 and the highest DC voltage for the PA to operate at.

The voltage level generator 504 will generate the one or more additional voltages 530 from the supply voltage 508. For example, the voltage level generator 504 may be a voltage divider, such as a switch capacitor voltage divider (SCVD), that divides the supply voltage 508 into the one or more additional voltages 530, resulting in the one or more additional voltage levels being less than the supply voltage 508 value. The voltage level generator 504, for example, may include a switched capacitor circuit that includes capacitors and switches that are opened and closed periodically, controlled by a non-overlapping clock signal. During specific switching phases, the capacitor on the input side is charged, and then the stored charge is moved to the output side through the switching action. The ratio of the input voltage to the output voltage depends on the capacitor values and the timing of the switches. The voltage level generator 504 may include multiple instances of switched capacitor circuits connected in series to generate multiple output voltages, resulting in multiple of the one or more additional voltages 530. The one or more additional voltage levels of the one or more additional voltages 530 may be integer multiples of the difference between the first voltage 510 level and the second voltage 520 level divide by the number of levels to be generated. The first voltage 510 and the second voltage 520 are the two voltages acting as highest and lowest levels, respectively, generated from the DC supply (e.g., by the supply generators 502A, 502B) of the DET module 500.

The supply modulator 506 then chooses between the first voltage 510, the second voltage 520, or one of the one or more additional voltages 530. The supply modulator 506 then connects a chosen voltage to the PA power supply based on the envelope of the data.

FIG. 5B illustrates an example radio frequency (RF) envelope 550 of the adaptive multi-level DET module 500 of FIG. 5A according to embodiments of the present disclosure.

As shown in FIG. 5B, the RF envelope 550 includes a plurality of RF load levels 560, including a first level 562, a second level 564, a third level 566, and a fourth level 568. The first level 562 may be a 100% load level, the second level 564 may be a 50% load level, the third level 566 may be a 25% load level, and the fourth level 568 may be a 10% load level. A plurality of voltage levels 570, such as the first voltage 510, the second voltage 520, and the one or more additional voltages 530 (two shown), provided to a power amplifier are adjusted based on the plurality of RF load levels 560. For example, the plurality of voltage levels 570 may be adjusted such that the center or peak 574 of a respective RF load level 572 of the plurality of RF load levels 560 is centered (e.g., at 576) between the highest (e.g., the first voltage 510) and lowest voltage (e.g., the second voltage) levels of the plurality of voltage levels 570. Centering the plurality of voltage levels 570 to the plurality of RF load levels 560 allows the plurality of voltage levels 570 to handle variations in the RF envelope 550 within the respective RF load level.

To support large variations in the RF envelope 550, the DET module 500 may adaptively change the voltage levels (e.g., the first voltage 510, the second voltage 520, and the one or more additional voltages 530) of the supply modulator 506 to conserve DC power. For each level of the total levels, M, of the plurality of RF load levels 560 (e.g., at 100%, 50%, 25%, and 10% of the peak voltage of the power amplifier), all voltage levels (e.g., the first voltage 510, the one or more additional voltages 530, and the second voltage 520) may be used for envelope tracking. The probability distribution function (PDF) of the large time frame is divided into smaller PDF sample and N voltage levels (four shown) are calculated and then applied. The effective total number of voltage levels for the example waveform is then N times M, resulting in 16 effective voltage levels for the waveform shown in FIG. 5B. This adaptive voltage level generation increases the efficiency of the power amplifier without reducing the efficiency of the digital envelope tracking module, increasing the overall system efficiency.

As the one or more additional voltage levels of the one or more additional voltages 530 generated are proportional to difference between the first voltage 510 and the second voltage 520, changing either the first voltage 510, the second voltage 520, or both, the one or more additional voltage levels for the DET system may be changed. The highest level, in this example, will be the supply voltage 508 and other voltage levels will be generated as:

$${V}_{L O} + n * ( ( {V}_{H I} - {V}_{LO} ) / {Nv}_{oltage} ) ,$$

where, V_{HI} is the first voltage 510, V_{LO} is the second voltage 520, n is the one or more additional voltage being generated, and Nv_{oltage} is the total number of one or more additional voltages 530 to be generated.

An additional inductive DC-DC converter, such as a step down (buck) converter, a step up (boost) converter, or a bidirectional converter, may be used by the supply generators 502A, 502B to change the voltage level of the first voltage 510 or the second voltage 520 by changing the supply voltage 508. The DC-DC converter may have high settling time, preventing such a method to be used on a data symbol-to-symbol basis where a time gap between two data symbols may be in the micro-second range.

Although FIGS. 5A-5B illustrate one example of an adaptive multi-level digital envelope tracking system, various changes may be made to FIGS. 5A-5B. For example, the one or more additional voltages may include one additional voltage or three additional voltages, creating a total of three voltage levels and five voltage levels, respectively, for the DET module to use as part of the DET system.

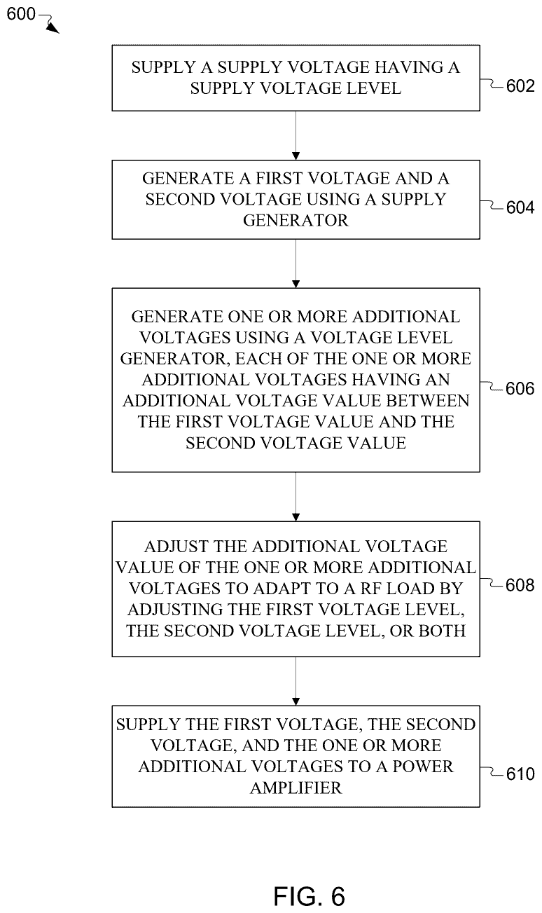

FIG. 6 illustrates an example adaptive multi-level digital envelope tracking method 600 according to embodiments of the present disclosure. An embodiment of the method illustrated in FIG. 6 is for illustration only. One or more of the components illustrated in FIG. 6 may be implemented in specialized circuitry configured to perform the noted functions or one or more of the components may be implemented by one or more processors executing instructions to perform the noted functions. Other embodiments of adaptive multi-level digital envelope tracking could be used without departing from the scope of this disclosure.

As illustrated in FIG. 6, a supply voltage 508 having a supply voltage level is supplied to a DET module 500 at step 602. For example, the supply voltage 508 may be supplied to the DET module 500 from a voltage source (e.g., the constant supply voltage source 454).

A first voltage 510 having a first voltage level and a second voltage 520 having a second voltage level is generated using a supply generator 502 of the DET module 500 at step 604. For example, a first supply generator 502A may be a DC-DC converter, such as a buck converter, that converts the supply voltage 508 into a lower voltage using switches, an inductor, and a capacitor to reduce the supply voltage level to generate the first voltage 510 and a second supply generator 502B may similarly generate the second voltage 520 from the supply voltage 508.

One or more additional voltages 530 are generated using a voltage level generator 504 of the DET module 500, each of the one or more additional voltages 530 having an additional voltage level between the first voltage 510 value and the second voltage 520 value at step 606. For example, the voltage level generator 504 may be a voltage divider, such as a switch capacitor voltage divider (SCVD), that divides the supply voltage 508 into the one or more additional voltages 530, resulting in the one or more additional voltage levels being less than the supply voltage 508 value.

The additional voltage level of the one or more additional voltages 530 is adjusted to adapt to a radio frequency (RF) load by adjusting the first voltage 510 level, the second voltage 520 level, or both at step 608. For example, the first supply generator 502A may adjust the first voltage level based on a high load value of the RF load, the second supply generator 502B may adjust the second voltage level based on a low load value of the RF load, or the first supply generator 502A may adjust the first voltage 510 level based on a high load value of the RF load and the second supply generator 502B may adjust the second voltage 520 level based on a low load value of the RF load. The supply generators 502A, 502B may adjust the first voltage 510, the second voltage 520, or both by temporarily connecting the power amplifier to a static level (e.g., to the first voltage 510 when adjusting the second voltage 520, to the second voltage 520 when adjusting the first voltage 510, or to the supply voltage 508 when adjusting both the first voltage 510 and the second voltage 520) while changing the one or more voltage levels in a background process. To do so, for example, the supply generators 502A, 502B may use a DC-DC converter to adjust the first voltage level, the second voltage level, or both when the power amplifier is connected to one of the static levels.

The first voltage 510, the second voltage 520, and the one or more additional voltages 530 is supplied to a power amplifier at step 610. For example, the first voltage 510, the second voltage 520, and the one or more additional voltages 530 may be supplied to a supply modulator 506 then the supply modulator 506 may selectively supply either the first voltage 510, the second voltage 520, or one of the one or more additional voltages 530 to the power amplifier. The supply modulator 506 may select either the first voltage 510, the second voltage 520, or one of the one or more additional voltages 530 based on the RF load.

Although FIG. 6 illustrates one example adaptive multi-level digital envelope tracking method 600, various changes may be made to FIG. 6. For example, while shown as a series of steps, various steps in FIG. 6 could overlap, occur in parallel, occur in a different order, or occur any number of times.

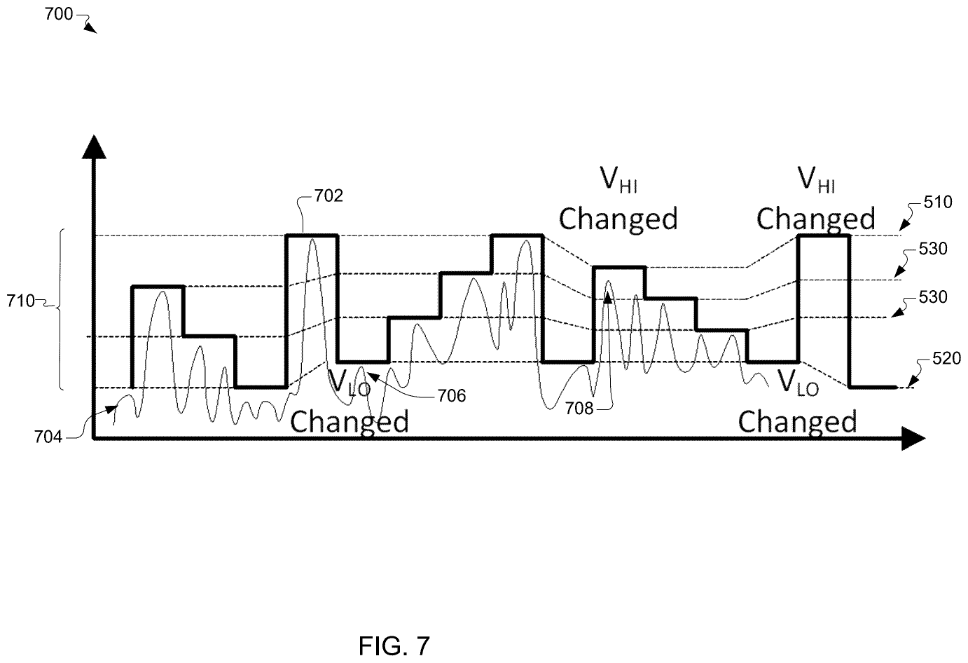

FIG. 7 illustrates an example voltage level chart 700 of an adaptive multi-level DET module 500 according to embodiments of the present disclosure. In particular, the voltage level chart 700 shows a power envelope 702 generated by the adaptive multi-level DET module 500 as a result of executing the method 600 of FIG. 6. The embodiment of the voltage level chart 700 shown in FIG. 7 is for illustration only. Other embodiments of the voltage level chart 700 could be used without departing from the scope of this disclosure.

As shown in FIG. 7, the power envelope 702 includes a plurality of adjustable voltage levels 710 (e.g., the first voltage 510, the second voltage 520, and two of the one or more additional voltages 530). The power envelope 702, due to the supply modulator 506, changes between the plurality of adjustable voltage levels 710 based on an RF load 704. As the RF load 704 changes, the highest voltage (e.g., the first voltage 510), the lowest voltage (e.g., the second voltage 520), or both of the plurality of adjustable voltage levels 710 may be adjusted to match the RF load 704. For example, when a low load value 706 in the RF load 704 increases beyond a set value of the second voltage 520, the second voltage 520 may be increased to surpass the low load value 706. Similarly, when a high load value 708 in the RF load 704 decreases beyond a set value of the first voltage 510, the first voltage 510 may be decreased to match the high load value 708. Alternatively, both the first voltage 510 and the second voltage 520 may be adjusted (either increased or decreased) to match increases or decreases in the low load value 706, the high load value 708, or both. When either of the first voltage 510 or the second voltage 520 are adjusted, so are the one or more additional voltages 530 as the one or more additional voltages 530 are generated based on the first voltage 510 and the second voltage 520.

To change a voltage level (e.g., the first voltage 510 or the second voltage 520), the output to PA is temporarily connected to one of the static levels (e.g., the first voltage 510, the second voltage 520, or the supply voltage 508). As discussed above, the DET module 500 tracks the RF load 704 of the power amplifier. The DET module 500 is aware of a future time slot and its voltage level requirement based on circuitry designed to process a received baseband signal to determine the RF load prior to processing in the DET module 500. As such, the DET module 500 may change a DC-DC converter in the first supply generator 502A or the second supply generator 502B when the power amplifier level will be connected to supply voltage 508, the first voltage 510, or the second voltage 520.

To adjust the second voltage 520, the power amplifier is temporarily connected to the highest level (first voltage 510). While the power amplifier is connected to first voltage 510, a new voltage level for the second voltage 520 will be created in the background. To adjust the first voltage 510, the power amplifier is temporarily connected to the second voltage 520 while a new voltage level for the first voltage 510 are generated. To make changes in both the first voltage 510 and the second voltage 520, the output to power amplifier may be connected to the highest level in the DET system, such as the supply voltage 508, while both the first voltage 510 and the second voltage 520 are be adjusted.

If, by adjusting a DC-DC converter in the supply generators 502A, 502B, M discrete number of levels may be generated, the total number of voltage levels generated by such an DET system is M times Nv_{oltage}. Here, M levels may support user load variation and Nv_{oltage} may support the PAPR of the waveform, increasing the usability and efficiency of the system.

Although FIG. 7 illustrates one example of a power envelope of an adaptive multi-level DET module 500, various changes may be made to FIG. 7. For example, a different quantity of voltage levels may be used, such as two or more voltage levels, three or more voltage levels, or four or more voltage levels.

The above flowchart illustrates example methods that may be implemented in accordance with the principles of the present disclosure and various changes could be made to the methods illustrated in the flowcharts herein. For example, while shown as a series of steps, various steps in each figure could overlap, occur in parallel, occur in a different order, or occur multiple times. In another example, steps may be omitted or replaced by other steps.

Although the present disclosure has been described with exemplary embodiments, various changes and modifications may be suggested to one skilled in the art. It is intended that the present disclosure encompass such changes and modifications as fall within the scope of the appended claims. None of the description in this application should be read as implying that any particular element, step, or function is an essential element that must be included in the claims scope. The scope of patented subject matter is defined by the claims.

What is claimed is:

1. A method comprising:
supplying a supply voltage having a supply voltage level to a digital envelope tracking system;
generating a first voltage having a first voltage level and a second voltage having a second voltage level using a supply generator of the digital envelope tracking system based on the supply voltage level;
generating one or more additional voltages using a voltage level generator of the digital envelope tracking system, each of the one or more additional voltages having an additional voltage level between the first voltage level and the second voltage level;
adjusting the additional voltage level of the one or more additional voltages to adapt to a radio frequency (RF) load by adjusting the first voltage level, the second voltage level, or both; and
supplying the first voltage, the second voltage, and the one or more additional voltages to a power amplifier.

2. The method of claim 1, wherein adjusting the additional voltage level of the one or more additional voltages to adapt to the RF load by adjusting the first voltage level, the second voltage level, or both comprises:
adjusting the first voltage level based on a high load value of the RF load;
adjusting the second voltage level based on a low load value of the RF load; or
adjusting the first voltage level based on a high load value of the RF load and adjusting the second voltage level based on a low load value of the RF load.

3. The method of claim 1, wherein adjusting the additional voltage level of the one or more additional voltages comprises:
temporarily connecting the power amplifier to a static level while changing the one or more voltage levels in a background process.

4. The method of claim 3, wherein adjusting the additional voltage level of the one or more additional voltages further comprises:
changing a DC-DC converter to adjust the first voltage level, the second voltage level, or both when the power amplifier is connected to the static level.

5. The method of claim 4, wherein changing the DC-DC converter to adjust the first voltage level, the second voltage level, or both when the power amplifier is connected to the static level comprises:
temporarily connecting the power amplifier to the first voltage level to adjust the second voltage level; or
temporarily connecting the power amplifier to the second voltage level to adjust the first voltage level; or
connecting an output to the power amplifier and the supply voltage to adjust the first voltage and the second voltage.

6. The method of claim 1, wherein supplying the first voltage, the second voltage, and the one or more additional voltages to the power amplifier comprises:
supplying the first voltage, the second voltage, and the one or more additional voltages to a supply modulator; and
selectively supplying either the first voltage, the second voltage, or one of the one or more additional voltages to the power amplifier using the supply modulator.

7. The method of claim 6, wherein selectively supplying either the first voltage, the second voltage, or one of the one or more additional voltages to the power amplifier using the supply modulator comprises:
selecting either the first voltage, the second voltage, or one of the one or more additional voltages based on the RF load.

8. An electronic device, comprising:
a transceiver configured to receive a baseband signal having a radio frequency (RF) load; and
a processor operably coupled to the transceiver, configured to cause the electronic device to:
supply a supply voltage having a supply voltage level to a digital envelope tracking system;
generate a first voltage having a first voltage level and a second voltage having a second voltage level using a supply generator of the digital envelope tracking system based on the supply voltage level;
generate one or more additional voltages using a voltage level generator of the digital envelope tracking system, each of the one or more additional voltages having an additional voltage level between the first voltage level and the second voltage level;
adjust the additional voltage level of the one or more additional voltages to adapt to the RF load by adjusting the first voltage level, the second voltage level, or both; and
supply the first voltage, the second voltage, and the one or more additional voltages to a power amplifier.

9. The electronic device of claim 8, wherein the processor, when causing the electronic device to adjust the additional voltage level of the one or more additional voltages to adapt to the RF load by adjusting the first voltage level, the second voltage level, or both, is further configured to cause the electronic device to:
adjust the first voltage level based on a high load value of the RF load;
adjust the second voltage level based on a low load value of the RF load; or
adjust the first voltage level based on a high load value of the RF load and adjusting the second voltage level based on a low load value of the RF load.

10. The electronic device of claim 8, wherein the processor, when causing the electronic device to adjust the additional voltage level of the one or more additional voltages, is further configured to cause the device to:
temporarily connect the power amplifier to a static level while changing the one or more voltage levels in a background process.

11. The electronic device of claim 10, wherein the processor, when causing the electronic device to adjust the additional voltage level of the one or more additional voltages, is further configured to cause the device to:
change a DC-DC converter to adjust the first voltage level, the second voltage level, or both when the power amplifier is connected to the static level.

12. The electronic device of claim 11, wherein the processor, when causing the electronic device to change the DC-DC converter to adjust the first voltage level, the second voltage level, or both when the power amplifier is connected to the static level, is further configured to cause the device to:
temporarily connect the power amplifier to the first voltage level to adjust the second voltage level; or
temporarily connect the power amplifier to the second voltage level to adjust the first voltage level; or
connect an output to the power amplifier and the supply voltage to adjust the first voltage and the second voltage.

13. The electronic device of claim 8, wherein the processor, when causing the electronic device to supply the first voltage, the second voltage, and the one or more additional voltages to the power amplifier, is further configured to cause the device to:
supply the first voltage, the second voltage, and the one or more additional voltages to a supply modulator; and
selectively supply either the first voltage, the second voltage, or one of the one or more additional voltages to the power amplifier using the supply modulator.

14. The electronic device of claim 13, wherein the processor, when causing the electronic device to selectively supply either the first voltage, the second voltage, or one of the one or more additional voltages to the power amplifier using the supply modulator, is further configured to cause the device to:
select either the first voltage, the second voltage, or one of the one or more additional voltages based on the RF load.

15. A non-transitory computer-readable medium comprising program code, that when executed by at least one processor of an electronic device, causes the electronic device to:
supply a supply voltage having a supply voltage level to a digital envelope tracking system;
generate a first voltage having a first voltage level and a second voltage having a second voltage level using a supply generator of the digital envelope tracking system based on the supply voltage level;
generate one or more additional voltages using a voltage level generator of the digital envelope tracking system, each of the one or more additional voltages having an additional voltage level between the first voltage level and the second voltage level;
adjust the additional voltage level of the one or more additional voltages to adapt to a radio frequency (RF) load by adjusting the first voltage level, the second voltage level, or both; and
supply the first voltage, the second voltage, and the one or more additional voltages to a power amplifier.

16. The non-transitory computer-readable medium of claim 15, wherein the program code, that when executed by the at least one processor, causes the electronic device to adjust the additional voltage level of the one or more additional voltages to adapt to the RF load by adjusting the first voltage level, the second voltage level, or both, further comprises program code, that when executed by the at least one processor, causes the electronic device to:
adjust the first voltage level based on a high load value of the RF load;
adjust the second voltage level based on a low load value of the RF load; or
adjust the first voltage level based on a high load value of the RF load and adjusting the second voltage level based on a low load value of the RF load.

17. The non-transitory computer-readable medium of claim 15, wherein the program code, that when executed by the at least one processor, causes the electronic device to adjust the additional voltage level of the one or more additional voltages, further comprises program code, that when executed by the at least one processor, causes the electronic device to:
temporarily connect the power amplifier to a static level while changing the one or more voltage levels in a background process.

18. The non-transitory computer-readable medium of claim 17, wherein the program code, that when executed by the at least one processor, causes the electronic device to adjust the additional voltage level of the one or more additional voltages, further comprises program code, that when executed by the at least one processor, causes the electronic device to:
change a DC-DC converter to adjust the first voltage level, the second voltage level, or both when the power amplifier is connected to the static level.

19. The non-transitory computer-readable medium of claim 18, wherein the program code, that when executed by the at least one processor, causes the electronic device to change the DC-DC converter to adjust the first voltage level, the second voltage level, or both when the power amplifier is connected to the static level, further comprises program code, that when executed by the at least one processor, causes the electronic device to:
temporarily connect the power amplifier to the first voltage level to adjust the second voltage level; or
temporarily connect the power amplifier to the second voltage level to adjust the first voltage level; or
connect an output to the power amplifier and the supply voltage to adjust the first voltage and the second voltage.

20. The non-transitory computer-readable medium of claim 15, wherein the program code, that when executed by the at least one processor, causes the electronic device to supply the first voltage, the second voltage, and the one or more additional voltages to the power amplifier, further comprises program code, that when executed by the at least one processor, causes the electronic device to:
supply the first voltage, the second voltage, and the one or more additional voltages to a supply modulator; and
selectively supply either the first voltage, the second voltage, or one of the one or more additional voltages to the power amplifier using the supply modulator.
